(19) United States
(12) Patent Application Publication
(10) Pub. No.: US 2025/0386629 A1
(43) Pub. Date: Dec. 18, 2025

(54) METHOD FOR PRODUCING AT LEAST ONE OPTOELECTRONIC DEVICE AND OPTOELECTRONIC DEVICE

(71) Applicant: ams-OSRAM International GmbH, Regensburg (DE)

(72) Inventors: Lei Chen, Changzhou (CN); Yu Ji, Suzhou Na (CN); TawMing Lau, Suzhou (CN); Wen Sun, Wuxi (CN)

(21) Appl. No.: 18/877,783

(22) PCT Filed: Jun. 29, 2022
(86) PCT No.: PCT/CN2022/102355

§ 371 Date: Dec. 20, 2024

(51) Int. Cl. H10H 29/01; H10H 29/85; H10H 29/851; H10H 29/852

(52) U.S. Cl. CPC H10H 29/0361; H10H 29/0362; H10H 29/0364; H10H 29/851; H10H 29/852; H10H 29/857

(57) ABSTRACT

In an embodiment a method for producing at least one optoelectronic device includes providing a substrate body, providing a substrate frame on the substrate body, wherein the substrate frame comprises at least one recess, providing at least one optoelectronic component on the substrate body, wherein the substrate frame and the at least one optoelectronic component are placed in relation to one another such that the at least one optoelectronic component is arranged in the at least one recess and providing a filler material in the at least one recess such that the at least one optoelectronic component is covered by the filler material, wherein the filler material is provided by a casting process.

### CROSS-REFERENCE TO RELATED APPLICATIONS

This patent application is a national phase filing under section 371 of PCT/CN2022/102355, filed Jun. 29, 2022, which is incorporated herein by reference in its entirety.

### TECHNICAL FIELD

An optoelectronic device and a manufacturing method for producing an optoelectronic device are specified. For example, the optoelectronic device is a semiconductor device suited for emitting electromagnetic radiation, for example in the infrared, visible or ultraviolet spectral range.

### BACKGROUND

In an exemplary method for producing an optoelectronic semiconductor device, a light-emitting semiconductor component of the optoelectronic semiconductor device may be encapsulated by a molding process. However, for semiconductor devices emitting white light, the molding process may lead to a low optical yield, for example to a broad distribution of color temperatures, because of capability limitations of conventional molding machines.

### SUMMARY

Embodiments provide a method for producing an optoelectronic device with improved efficiency.

Further embodiments provide an optoelectronic device having improved efficiency.

According to at least one embodiment of a method for producing at least one optoelectronic device, it comprises a step of providing a substrate body. For example, the substrate body may be flat, wherein a height of the substrate body is small in comparison to its length and width. The height may determine a vertical dimension measured along a vertical direction and the length and width may be lateral dimensions measured along lateral directions, which each run obliquely, especially perpendicularly, to the vertical direction, and which run obliquely, especially perpendicularly, to each other.

According to at least one embodiment, the method comprises a step of providing a substrate frame on the substrate body, wherein the substrate frame comprises at least one recess. The at least one recess may fully penetrate the substrate frame, for example in the vertical direction, and extend from a first main surface to a second main surface of the substrate frame, wherein the second main surface is opposite to the first main surface. The at least one recess may be laterally surrounded by one or more side walls of the substrate frame. The at least one recess may be essentially rectangular in a plan view of the first main surface, wherein “essentially” means “at least approximately”. In particular, a substrate frame is provided which comprises a plurality of recesses. The substrate frame may be provided with one of its main surfaces on a main surface of the substrate body. In the context of the present application, a “main surface” of an element is a surface which is essentially parallel to a main extension plane of the element.

According to at least one embodiment, the method comprises a step of providing at least one optoelectronic component on the substrate body. For example, the optoelectronic component may be a bare semiconductor chip. Alternatively, the optoelectronic component may be a packaged semiconductor chip.

The at least one optoelectronic component may be provided on a main surface of the substrate body. Especially, the substrate frame and the at least one optoelectronic component are placed in relation to one another in such a way that the at least one optoelectronic component is arranged in the at least one recess. For example, the substrate frame is provided on the substrate body first, and the at least one optoelectronic component is arranged in the at least one recess afterwards. Alternatively, the at least one optoelectronic component may be mounted on the substrate body first, and the substrate frame may be arranged on the substrate body afterwards.

According to at least one embodiment, the method comprises a step of providing a filler material in the at least one recess in such a way that the at least one optoelectronic component is covered by the filler material. Especially, the at least one optoelectronic component may be encapsulated by the filler material. Preferably, the filler material is provided by a casting process. The casting process includes pouring the filler material as a liquid material into the at least one recess and allowing the filler material to solidify.

According to at least one embodiment of a method for producing at least one optoelectronic device, it comprises the following steps, preferably in the cited order:
providing a substrate body,
providing a substrate frame on the substrate body, wherein the substrate frame comprises at least one recess,
providing at least one optoelectronic component on the substrate body, wherein the substrate frame and the at least one optoelectronic component are placed in relation to one another in such a way that the at least one optoelectronic component is arranged in the at least one recess,
providing a filler material in the at least one recess in such a way that the at least one optoelectronic component is covered by the filler material,
wherein the filler material is provided by a casting process.

The casting process has the advantage that it causes lower costs than a compression molding process, for example.

According to at least one embodiment or configuration, the substrate frame is formed with a height which is the smaller the higher a viscosity of the filler material is. The substrate frame or the one or more side walls of the substrate frame, which laterally delimit/s the at least one recess and thus the filler material in the at least one recess, is/are provided to prevent the filler material from flowing away and to concentrate the filler material in a special area of the substrate body. For a filler material having a higher viscosity, a resistance to deformation or flowing away is higher as for a filler material having a lower viscosity, and thus a barrier or side wall/s can be smaller. For example, the height of the substrate frame is at least as big as the height of the at least one optoelectronic component.

According to at least one embodiment or configuration, the filler material is dispensed in the at least one recess by a casting needle. The casting needle allows for a precise dosing of the filler material in the at least one recess. And thus the casting process provides for high accuracy.

According to at least one embodiment or configuration, the filler material comprises or consists of a plastic material. The filler material may comprise or consist of at least one of the following materials: silicone, epoxy. Especially, the filler material or at least one of its substances is selected from a group of materials which are suitable for encapsulation of an optoelectronic component like a light-emitting semiconductor component, for example.

According to at least one embodiment or configuration, a centrifuge process follows the casting process. In particular, the centrifuge process is conducted before a solidification of the filler material occurs. For example, the centrifuge process includes spinning the arrangement of the substrate body, the substrate frame and the filler material around a vertical axis, for example a vertical center axis of the arrangement.

According to at least one embodiment or configuration, the filler material comprises an admixture material. The admixture material may have a higher density than the other substance or substances of the filler material, for example than the plastic material like silicone or epoxy as mentioned above. During the centrifuge process, a radial acceleration may cause the higher-density admixture material to settle closer to the substrate body, while the lower-density substance(s) rise(s) to a top of the admixture material away from the substrate body. Hence, the admixture material may undergo sedimentation due to the centrifuge process and form a sediment layer. And the lower-density substance(s) like silicone or epoxy may form a cover layer on the sediment layer. The cover layer, which may protect the sediment layer, can improve product lifetime of the at least one optoelectronic device produced in this way.

According to at least one embodiment or configuration, the filler material comprises an admixture material which is a phosphor material. The phosphor material is a wavelength-converting material, which is configured to convert primary radiation of a first wavelength, for example generated in an optoelectronic component, into secondary radiation of a second, longer wavelength different from the first wavelength. Due to the casting process, which provides for a relatively high accuracy, an optical yield of an optoelectronic device emitting mixed color light, for example white light, can be improved.

According to at least one embodiment or configuration, a substrate body is provided, which comprises or consists of at least one of the following materials: metal, ceramics. For example, the substrate body may be a patterned substrate body, for example a leadframe, which may comprise or consist of copper.

According to at least one embodiment or configuration, a substrate frame is provided, which comprises or consists of glass and/or a plastic material, for example an epoxy.

According to at least one embodiment or configuration, the substrate frame is a molded body. In other words, the substrate frame may be produced by a molding process and can be directly applied on the substrate body. Alternatively, the substrate frame may be a separate, self-supporting element, which is attached to the substrate body, for example by an attachment layer.

According to at least one embodiment or configuration, a plurality of optoelectronic devices are produced, each of which comprises a substrate element, an optoelectronic component arranged on the substrate element and a cover element arranged on the optoelectronic component, wherein producing the plurality of optoelectronic devices comprises:
providing a plurality of optoelectronic components on the substrate body, wherein the substrate frame and the plurality of optoelectronic components are placed in relation to one another in such a way that at least two optoelectronic components are arranged in the at least one recess, and
conducting a singulation process through the filler material and the substrate body between adjacent optoelectronic components.

The filler material may be divided into a plurality of cover elements during singulation. The at least one cover element formed from the filler material may correspond to the filler material especially with respect to its layer structure and/or material composition as mentioned above. Moreover, the substrate body may be divided into a plurality of substrate elements during singulation. The at least one substrate element formed from the substrate body may correspond to the substrate body especially with respect to its physical structure and/or material composition as mentioned above.

Placing more than one optoelectronic component in one recess allows for an efficient production of a plurality of optoelectronic devices.

According to at least one embodiment or configuration, the optoelectronic components are arranged in rows and columns in the at least one recess. Especially, the optoelectronic components are arranged in rows and columns in every recess.

According to at least one embodiment or configuration, the substrate frame is provided with a plurality of recesses, which are arranged in rows and columns.

The method described above is suitable for the production of at least one optoelectronic device described below in more detail. The features described in connection with the method can therefore also apply to the optoelectronic device, and vice versa.

According to at least one embodiment of an optoelectronic device, it comprises a substrate element and an optoelectronic component arranged on the substrate element. The substrate element may comprise a first contact region and a second contact region for electrically contacting the optoelectronic device from outside. And the optoelectronic component may be electrically connected to the first contact region and the second contact region. For example, the optoelectronic component may be mounted on one of the contact regions and may be electrically connected to the other one, for example by a wire bond. Alternatively, the optoelectronic component may be mounted on a mounting region of the substrate element different from the first contact region and the second contact region and may be electrically connected to the first and second contact regions, for example in each case by a wire bond.

According to at least one embodiment, the optoelectronic device comprises a cover element, which is arranged on the optoelectronic component. The cover element may cover a main surface of the optoelectronic component, wherein the main surface is arranged on a side of the optoelectronic component facing away from the substrate element. Moreover, the cover element may cover one or more side surfaces of the optoelectronic component, wherein the one or more side surfaces run obliquely, for example perpendicularly, to the main surface. Furthermore, the cover element may be arranged on the substrate element, for example on a main surface of the substrate element facing the optoelectronic component.

According to at least one embodiment, the cover element comprises a first cover layer and a second cover layer, wherein the first cover layer is at least partly arranged between the optoelectronic component and the second cover layer and is a sediment layer. As mentioned above, the filler material from which the cover element is produced can be subjected to a centrifuge process, wherein the admixture material may undergo sedimentation and form a sediment layer and result in a first cover layer on the optoelectronic device. And the lower-density substance(s), which may be one or more plastic materials like silicone and/or epoxy, may form a cover layer on the sediment layer and result in a second cover layer on the first cover layer. Hence, the second cover layer may comprise or consist of at least one of the following materials: silicone, epoxy. The second cover layer, which may protect the first cover layer or sediment layer, can improve product lifetime of the optoelectronic device.

According to at least one embodiment of an optoelectronic device, it comprises:
a substrate element,
an optoelectronic component arranged on the substrate element, and
a cover element, which is arranged on the optoelectronic component and comprises a first cover layer and a second cover layer, wherein the first cover layer is at least partly arranged between the optoelectronic component and the second cover layer and is a sediment layer.

According to at least one embodiment or configuration, the first cover layer is a phosphor layer. And the optoelectronic component can be a light-emitting semiconductor component. The phosphor layer may be configured to convert primary radiation of a first wavelength, for example blue light, generated by the light-emitting semiconductor component into secondary radiation of a second, longer wavelength, for example yellow light, such that the optoelectronic device emits mixed color light, for example white light. Due to the casting process, which provides for a relatively high accuracy, an optical yield of the optoelectronic device emitting mixed color light, for example white light, can be improved.

According to at least one embodiment or configuration, the optoelectronic device may be a so-called QFN (Quad Flat NO Leads) device, which allows for surface-mount technology and has a near-chip-scale plastic-encapsulated package made with a planar copper lead frame substrate. In other words, the cover element may have chip-scale size, and the substrate element may be a copper leadframe element.

The optoelectronic device presented here may be a light-emitting semiconductor device, which is suitable for illumination, AR (augmented reality), VR (virtual reality) and display applications, or may be a sensor device.

### BRIEF DESCRIPTION OF THE DRAWINGS

Further preferred embodiments and further developments of the optoelectronic device and the manufacturing method for producing the optoelectronic device will become apparent from the exemplary embodiments explained below in conjunction with the Figures.

FIGS. 1A to 1C, 2 and 3A to 3C show schematic cross-sectional and plan views of steps of an exemplary embodiment of a method for producing at least one optoelectronic device;

FIGS. 4 and 5 show schematic cross-sectional views of different exemplary embodiments of optoelectronic devices; and

FIGS. 6A, 6B, 7, 8, 9A, 9B and 10 show schematic cross-sectional, side and plan views of steps of a comparative example of a method for producing at least one optoelectronic device.

Identical, equivalent or equivalently acting elements may be indicated with the same reference numerals in the figures. The figures are schematic illustrations and thus not necessarily true to scale. Comparatively small elements and particularly layer thicknesses can rather be illustrated exaggeratedly large for the purpose of better clarification.

### DETAILED DESCRIPTION OF ILLUSTRATIVE EMBODIMENTS

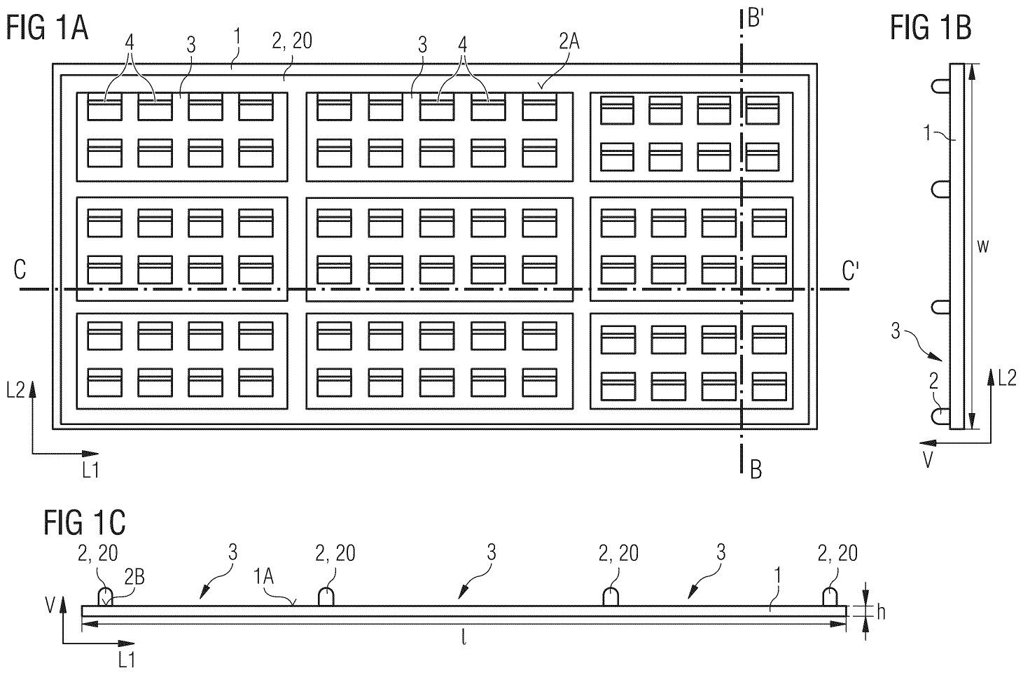

In connection with FIGS. 1A to 3C an exemplary embodiment of a method for producing at least one optoelectronic device is described.

The method comprises providing a substrate body 1, which is illustrated in the schematic plan view of FIG. 1A and the schematic cross-sectional views of FIGS. 1B and 1C. The cross section shown in FIG. 1B is taken along a plane BB′ and the cross section shown in FIG. 1C is taken along plane CC′.

In this exemplary embodiment, the substrate body 1 is flat, having a height h which is small in comparison to its length l and width w. The height determines a vertical dimension measured along a vertical direction V and the length l and width w determine lateral dimensions measured along lateral directions L1, L2, which each run obliquely, especially perpendicularly, to the vertical direction V, and which run obliquely, especially perpendicularly, to each other.

In this exemplary embodiment, the substrate body 1 is a metal body. For example, the substrate body 1 is a patterned substrate body, for example a leadframe, which may comprise or consist of copper. Alternatively, the substrate body 1 may be a ceramics body, for example.

The method further comprises providing a substrate frame 2 on the substrate body 1, wherein the substrate frame 2 comprises a plurality of recesses 3 (see FIGS. 1A to 1C). The recesses 3 fully penetrate the substrate frame 2 in the vertical direction V and extend from a first main surface 2A to a second main surface 2B of the substrate frame 2, wherein the second main surface 2B is opposite to the first main surface 2A (see FIGS. 1A and 1C). The recesses 3 are each laterally surrounded by side walls 20 of the substrate frame 2. The recesses 3 each have an essentially rectangular shape in a plan view of the first main surface 2A, wherein “essentially” means “at least approximately”. The substrate frame 2 has a grid-like shape.

In this exemplary embodiment, the substrate frame 2 is a molded body produced by a molding process on the substrate body 1 and comprises or consists of plastic material like for example an epoxy. However, it is also possible that the substrate frame 2 is a separate, self-supporting element, which is attached to the substrate body 1. In this case, the substrate frame 2 may comprise or consist of glass.

The substrate frame 2 is provided with its second main surface 2B on a main surface 1A of the substrate body 1 (see FIG. 1C).

The method further comprises providing a plurality of optoelectronic components 4 on the substrate body 1. The optoelectronic components 4 are arranged on the main surface 1A of the substrate body 1. The substrate frame 2 and the optoelectronic components 4 are placed in relation to one another in such a way that several optoelectronic components 4 are arranged in every recess 3. The optoelectronic components 4 are arranged in rows and columns in the recesses 3. In other words, the optoelectronic components 4 of every recess 3 are arranged in a matrix-like manner.

The substrate frame 2 may be provided on the substrate body 1 first, and the optoelectronic components 4 may be arranged in the recesses afterwards. Alternatively, the optoelectronic components 4 may be mounted on the substrate body 1 first, and the substrate frame 2 may be arranged on the substrate body 1 afterwards.

For example, the optoelectronic components 4 are bare semiconductor chips. Alternatively, the optoelectronic components 4 may be packaged semiconductor chips. Especially, the optoelectronic components 4 are light-emitting semiconductor components emitting electromagnetic radiation in the ultraviolet to infrared spectral range.

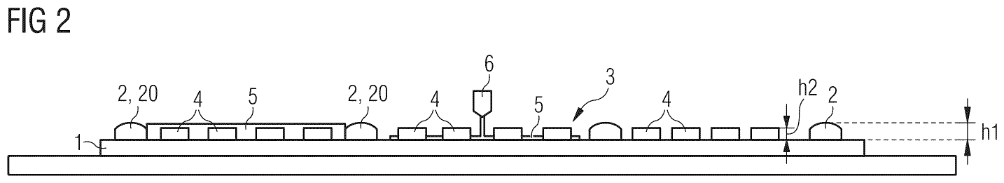

As illustrated in the cross-sectional view of FIG. 2, the method further comprises providing a filler material 5 in the recesses 3. The recesses 3 may be filled with the filler material 5 one after the other.

The filler material 5 is provided by a casting process. The casting process includes pouring the filler material 5 as a liquid material into the recesses 3 and allowing the filler material to solidify. The filler material 5 is dispensed by a casting needle 6, which allows for a precise dosing of the filler material 5 in the recesses 3. And thus the casting process provides for high accuracy.

The substrate frame 2 is formed with a height h1 which is the smaller the higher a viscosity of the filler material 5 is. The substrate frame 2 or the side walls 20 of the substrate frame 2, which laterally delimit/s the recesses 3 and thus the filler material 5 in the recesses 3, is/are provided to prevent the filler material 5 from flowing away and to concentrate the filler material 5 in areas of the substrate body 1 where the optoelectronic components 4 are arranged. For a filler material 5 having a higher viscosity, a resistance to deformation or flowing away is higher as for a filler material 5 having a lower viscosity, and thus a barrier or the side walls 20 can be smaller. For example, a height h1 of the substrate frame 2 is at least as big as a height h2 of the optoelectronic components 4.

For example, the filler material 5 comprises or consists of a plastic material. The filler material may comprise or consist of at least one of the following materials: silicone, epoxy.

The filler material 5 is filled in the recesses 3 in such a way that the optoelectronic components 4 are covered, for example encapsulated, by the filler material 5. Hence, the filler material 5 or at least one of its substances is selected from a group of materials which are suitable for encapsulation of the optoelectronic components 4.

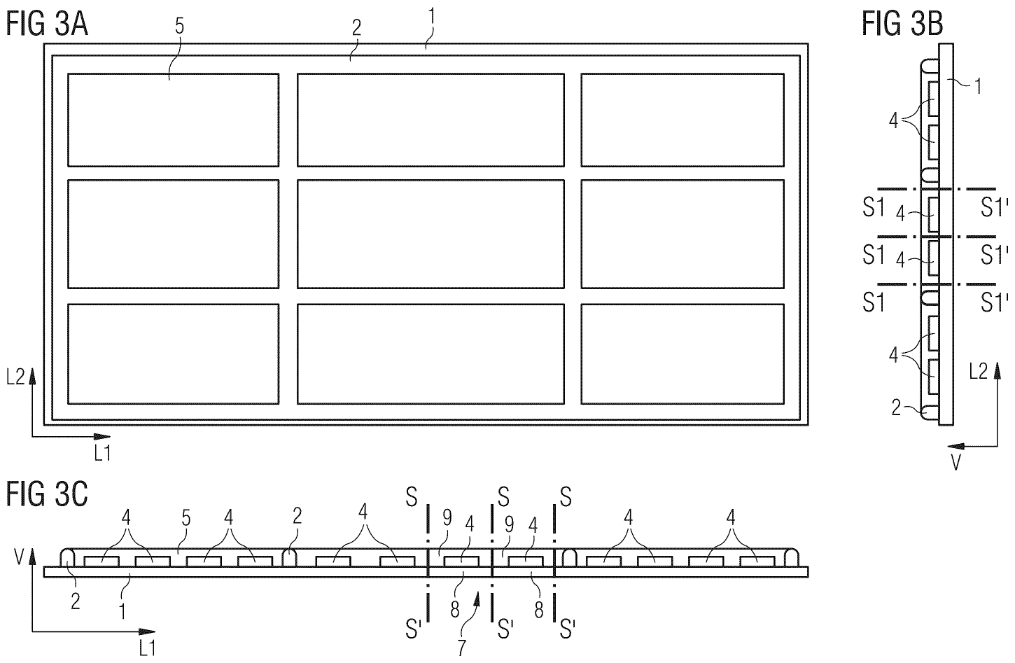

After solidification of the filler material 5, a singulation process is conducted through the filler material 5 and the substrate body 1 between adjacent optoelectronic components 4 (see FIGS. 3A to 3C). The singulation process is conducted along separation planes SS′ parallel to the vertical direction V and the lateral direction L2. Moreover, the singulation process is conducted along separation planes S1S1′ parallel to the vertical direction V and the lateral direction L1.

Hence, the arrangement of the substrate body 1, the substrate frame 2 and the filler material 5 may be divided into a plurality of optoelectronic devices 7, wherein the filler material 5 is divided into a plurality of cover elements 9 and the substrate body 1 is divided into a plurality of substrate elements 8 during singulation.

Placing more than one optoelectronic component 4 in one recess allows for an efficient production of a plurality of optoelectronic devices 7.

Before solidification, the method may comprise a centrifuge process following the casting process (not shown). For example, the centrifuge process includes spinning the arrangement of the substrate body 1, the substrate frame 2 and the filler material 5 around a vertical axis, for example a vertical center axis of the arrangement.

The filler material 5 may comprise an admixture material (not shown). Especially, the admixture material has a higher density than the one or more other substances of the filler material 5, which may be plastic materials like silicone or epoxy as mentioned above.

During the centrifuge process, a radial acceleration causes the higher-density admixture material to settle closer to the substrate body 1, while the lower-density substance(s) rise(s) to a top of the admixture material away from the substrate body 1. Hence, the admixture material undergoes sedimentation due to the centrifuge process and forms a sediment layer. And the lower-density substance(s) like silicone and/or epoxy form(s) a cover layer on the sediment layer. The cover layer, which may protect the sediment layer, can improve product lifetime of the optoelectronic devices produced in this way.

For example, the filler material 5 comprises an admixture material which is a phosphor material. The phosphor material is a wavelength-converting material, which is configured to convert primary radiation of a first wavelength, for example generated in the optoelectronic components 4, into secondary radiation of a second, possibly longer wavelength different from the first wavelength. Due to the casting process, which provides for a relatively high accuracy, an optical yield of the optoelectronic devices 7 emitting mixed color light may be enhanced.

In addition, the method may have any of the features, characteristics and advantages mentioned in connection with the further exemplary embodiments.

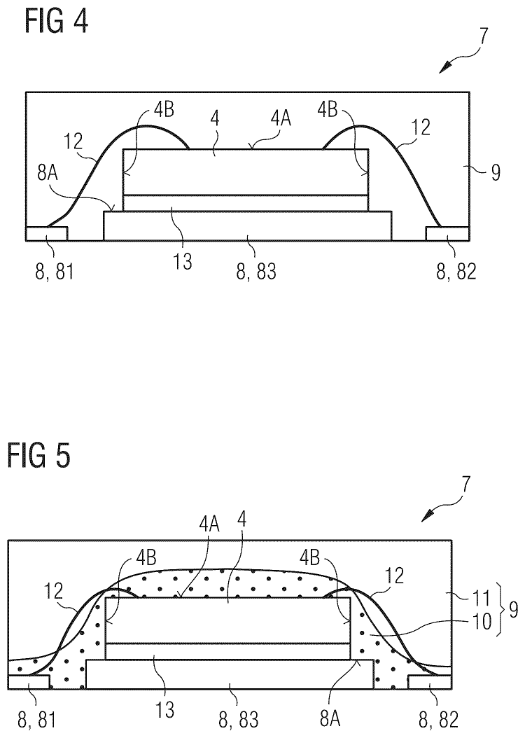

FIGS. 4 and 5 show schematic cross-sectional views of different exemplary embodiments of optoelectronic devices 7 which may be produced by a method as described in connection with FIGS. 1 to 3.

According to the exemplary embodiments, the optoelectronic device 7 comprises a substrate element 8 and an optoelectronic component 4 arranged on the substrate element 8. As the substrate element 8 may be formed from the substrate body 1 as mentioned above (see FIGS. 1 to 3), the substrate element 8 may correspond to the substrate body 1 especially with respect to its physical structure and/or material composition as mentioned above.

The substrate element 8 comprises a first contact region 81 and a second contact region 82 for electrically contacting the optoelectronic device 7 from outside. And the optoelectronic component 4 is electrically connected to the first contact region 81 and the second contact region 82. The optoelectronic component 4 is attached to a mounting region 83 of the substrate element 8 by an attachment layer 13, wherein the mounting region 83 is different from the first contact region 81 and the second contact region 82. And the optoelectronic component 4 is electrically connected to the first and second contact regions 81, 82 in each case by a wire bond 12. Alternatively, the optoelectronic component 4 may be mounted on one of the contact regions 81, 82 and may be electrically connected to the other one by a wire bond. A separate mounting region 83 is not necessary in this case.

The optoelectronic device 7 comprises a cover element 9, which is arranged on the optoelectronic component 4. The cover element 9 covers a main surface 4A of the optoelectronic component 4, wherein the main surface 4A is arranged on a side of the optoelectronic component 4 facing away from the substrate element 8. Moreover, the cover element 9 covers side surfaces 4B of the optoelectronic component 4, wherein the side surfaces 4B run obliquely, for example perpendicularly, to the main surface 4A. Furthermore, the cover element 9 is arranged on the substrate element 8, for example on a main surface 8A of the substrate element 8 facing the optoelectronic component 4 and in interspaces between the different regions 81, 82, 83 of the substrate element 8.

The cover element 9 may be formed from the filler material 5 (see FIGS. 3A to 3C, for example) and thus correspond to the filler material 5 especially with respect to its layer structure and/or material composition as mentioned above.

While the cover element 9 shown in FIG. 4 has a single layer structure, the cover element 9 shown in FIG. 5 has a multilayer structure.

The cover element 9 shown in FIG. 4 may comprise a base material, for example a plastic material like silicone and/or epoxy, and an admixture material, for example a phosphor material, which is distributed in the base material. The optoelectronic device 7 shown in FIG. 4 can be produced without conducting a centrifuge process.

The cover element 9 shown in FIG. 5 comprises a first cover layer 10 and a second cover layer 11, wherein the first cover layer 10 is at least partly arranged between the optoelectronic component 4 and the second cover layer 11.

The first cover layer 10 is a sediment layer. In this case, a centrifuge process is conducted as described in connection with FIGS. 1 to 3, wherein the filler material 5 comprises an admixture material which undergoes sedimentation and forms a sediment layer and results in the first cover layer 10 on the optoelectronic component 4, while the lower-density substance(s), for example plastic material(s) like silicone and/or epoxy, form(s) a cover layer on the sediment layer and result(s) in the second cover layer 11 on the first cover layer 10. For example, the first cover layer 10 is a phosphor layer.

The optoelectronic component 4 can be a light-emitting semiconductor component, wherein the phosphor layer 10 is configured to convert primary radiation of a first wavelength, for example blue light, generated by the light-emitting semiconductor component 4 into secondary radiation of a second, longer wavelength, for example yellow light, such that the optoelectronic device 7 emits mixed color light, for example white light. Due to the casting process, which provides for a relatively high accuracy, an optical yield of the optoelectronic device 7 emitting mixed color light, for example white light, can be improved.

The optoelectronic device 7 may be a so-called QFN (Quad Flat NO Leads) device, which allows for surface-mount technology and has a near-chip-scale plastic-encapsulated package or cover element 9 made with a planar copper lead frame substrate or substrate element 8.

In addition, the optoelectronic device 7 may have any of the features, characteristics and advantages mentioned in connection with the method.

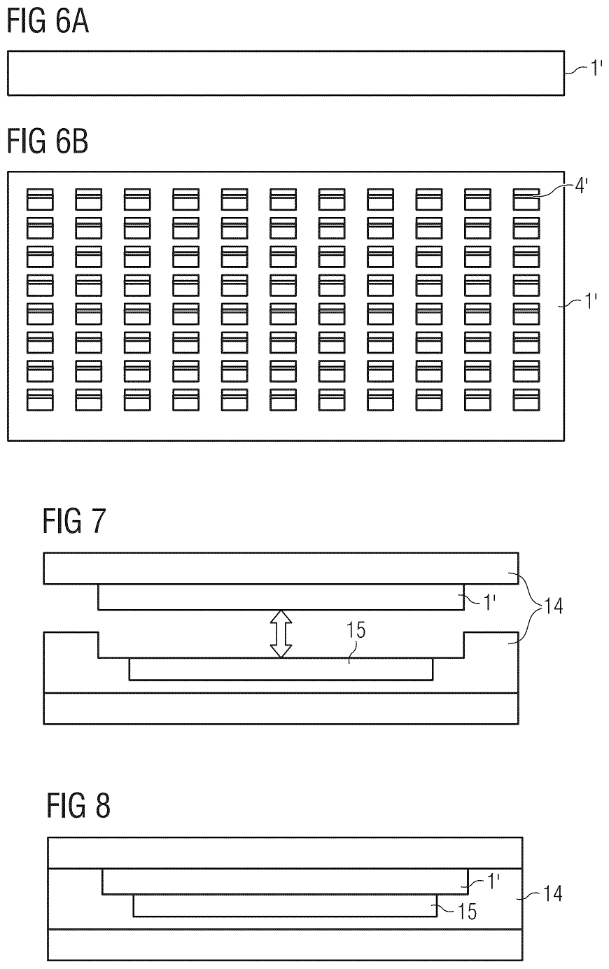

In connection with FIGS. 6A to 10, a comparative example of a method for producing optoelectronic devices is described.

As shown in the schematic cross-sectional view of FIG. 6A and in the schematic plan view of FIG. 6B a substrate body 1′ is provided with a plurality of optoelectronic devices 4′ arranged thereon (see FIG. 6B).

As shown in the schematic cross-sectional views of FIGS. 7 and 8, a mold case 14 is provided, and the substrate body 1′ with the plurality of optoelectronic devices arranged thereon is provided with a molding material 15 in a compression molding process. A centrifuge process cannot be conducted because the molding material 15 does not have the necessary liquid consistency.

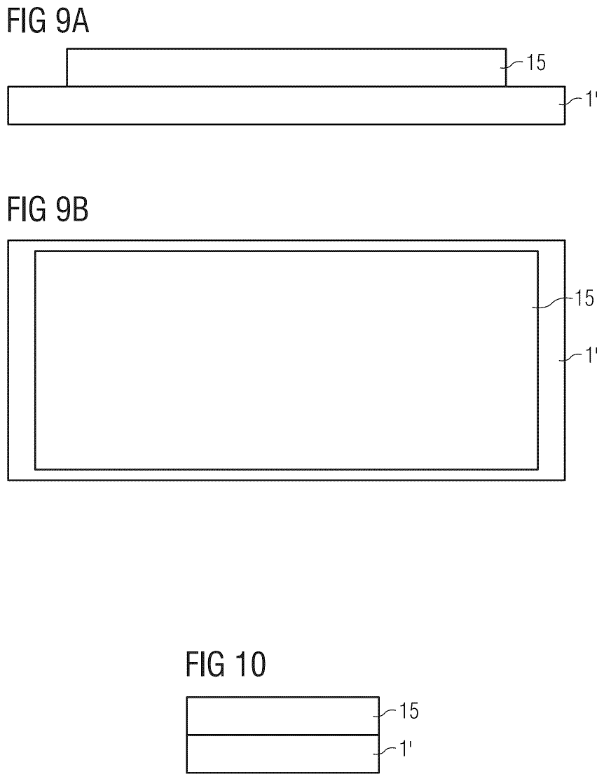

As shown in the schematic side view of FIG. 9A and in the schematic plan view of FIG. 9B, the encapsulated arrangement is turned around and singulated (see FIG. 10).

In comparison to the casting process, the molding process costs are higher and the optical yield is lower due to the molding machine capability limitation.

The scope of protection of the invention is not limited to the examples given hereinabove. The invention is embodied in each novel characteristic and each combination of characteristics, which particularly includes every combination of any features which are stated in the claims, even if this feature or this combination of features is not explicitly stated in the claims or in the examples.

1.-17. (canceled)

18. A method for producing at least one optoelectronic device, the method comprising:
providing a substrate body;
providing a substrate frame on the substrate body, wherein the substrate frame comprises at least one recess;
providing at least one optoelectronic component on the substrate body, wherein the substrate frame and the at least one optoelectronic component are placed in relation to one another such that the at least one optoelectronic component is arranged in the at least one recess; and
providing a filler material in the at least one recess such that the at least one optoelectronic component is covered by the filler material,
wherein the filler material is provided by a casting process.

19. The method according to claim 18, wherein the substrate frame is formed with a height which is at least as large as a height of the at least one optoelectronic component.

20. The method according to claim 18, wherein the filler material comprises at least silicone or epoxy.

21. The method according to claim 18, wherein a centrifuge process follows the casting process.

22. The method according to claim 18, wherein the filler material comprises an admixture material.

23. The method according to claim 22, wherein the admixture material undergoes sedimentation due to a centrifuge process and forms a sediment layer.

24. The method according to claim 18, wherein the filler material comprises an admixture material, which is a phosphor material.

25. The method according to claim 18, wherein the substrate body comprises a metal or a ceramic.

26. The method according to claim 18, wherein the substrate frame comprises epoxy or glass.

27. The method according to claim 18, wherein the substrate frame is a molded body.

28. The method according to claim 18,
wherein a plurality of optoelectronic devices are produced, each of which comprises a substrate element, an optoelectronic component arranged on the substrate element and a cover element arranged on the optoelectronic component, and
wherein producing the plurality of optoelectronic devices comprises:
providing a plurality of optoelectronic components on the substrate body, wherein the substrate frame and the plurality of optoelectronic components are placed in relation to one another in such a way that at least two optoelectronic components are arranged in the at least one recess, and
conducting a singulation process through the filler material and the substrate body between adjacent optoelectronic components.

29. The method according to claim 28, wherein the optoelectronic components are arranged in rows and columns in the at least one recess.

30. The method according to claim 18, wherein the substrate frame comprises a plurality of recesses, which are arranged in rows and columns.

31. An optoelectronic device comprising:
a substrate element;
an optoelectronic component arranged on the substrate element; and
a cover element arranged on the optoelectronic component and comprising a first cover layer and a second cover layer,
wherein the first cover layer is at least partly arranged between the optoelectronic component and the second cover layer and is a sediment layer.

32. The optoelectronic device according to claim 31, wherein the first cover layer is a phosphor layer.

33. The optoelectronic device according to claim 31, wherein the second cover layer comprises silicone or epoxy.

34. The optoelectronic device according to claim 31, wherein the optoelectronic component is a light-emitting semiconductor component.

35. The optoelectronic device according to claim 31, wherein the optoelectronic device is free of a frame element laterally delimiting the cover element.

36. A method for producing a plurality of optoelectronic devices, the method comprising:
providing a substrate body;
providing a substrate frame on the substrate body, wherein the substrate frame comprises a plurality of recesses;
providing a plurality of optoelectronic components on the substrate body, wherein the substrate frame and the plurality of optoelectronic components are placed in relation to one another such that at least two optoelectronic components are arranged in every recess;
providing a filler material in the plurality of recesses such that the at least two optoelectronic components are covered by the filler material, wherein the filler material is provided by a casting process and comprises an admixture material;
performing a centrifuge process after the casting process, wherein the admixture material undergoes sedimentation due to the centrifuge process and forms a sediment layer; and
conducting a singulation process through the filler material and the substrate body between adjacent optoelectronic components.
